(19) United States
(12) Patent Application Publication
(10) Pub. No.: US 2014/0002140 A1
(43) Pub. Date: Jan. 2, 2014

(54) LEVEL SHIFTER CAPABLE OF PULSE FILTERING AND BRIDGE DRIVER USING THE SAME

(71) Applicant: Yen-Ping Wang, Taipei City (TW)

(72) Inventor: Yen-Ping Wang, Taipei City (TW)

(21) Appl. No.: 13/535,950

(22) Filed: Jun. 28, 2012

(51) Int. Cl. H03K 3/00; H03L 5/00

(52) U.S. Cl. 327/108; 327/333

(57) ABSTRACT

A level shifter capable of pulse filtering and a bridge driver using the same, the level shifter capable of pulse filtering being used for up shifting a first clock signal and a second clock signal to provide a set signal and a reset signal, and for preventing noise on the first clock signal or on the second clock signal from altering the states of the set signal and the reset signal.

### BACKGROUND OF THE INVENTION

1. Field of the Invention

The present invention relates to a level shifter, and more particularly to a level shifter capable of pulse filtering in a half-bridge or full-bridge driver.

2. Description of the Related Art

To describe the related art of the present invention, the relation between a level shifter and a half-bridge or full-bridge driver shall be introduced first. Please refer to FIG. 1, which shows the architecture of a typical half-bridge driver 100. As shown in FIG. 1, the typical half-bridge driver 100 at least includes a pulse generator 101, a level shifter 102, a pulse filter 103, and a latch 104.

The pulse generator 101 is used for generating a first clock signal CLK and a second clock signal CLKB, wherein the first clock signal CLK is interleaved with the second clock signal CLKB. The level shifter 102 is used to up shift the first clock signal CLK and the second clock signal CLKB from low side to provide counterpart signals for the pulse filter 103 at high side. The pulse filter 103 is used for cancelling a common-mode glitch interference accompanying the power lines of V_{BOOT} and HB, and generating a set signal V_{SET} and a reset signal V_{RESET} to the latch 104. The latch 104 is used for sending a signal to a driver to switch a high-side power MOSFET. During the switching, a glitch is generated due to the capacitive characteristic of a capacitor C_{BOOT}, i.e., the voltage difference hold between the two plates of a capacitor will not change abruptly. As a result, a certain period the capacitor takes to reach a stable state causes a glitch period. The pulse filter 103 is therefore used to deal with the glitch problem to prevent false triggering of the latch 104.

One solution to improve the glitch immunity of the half-bridge or full-bridge driver is to use a level shifter of a symmetric structure. Please refer to FIG. 2, which shows a circuit diagram of a prior art level shifter 200 driving a latch 210. As shown in FIG. 2, the prior art level shifter 200 comprises a pair of loading resistors 201-202, a first pair of NMOS transistors 203-204 and a second pair of NMOS transistors 205-206.

By the symmetric structure, the voltage potentials V_{SET} and V_{RESET} at the drain terminals of the first pair of NMOS transistors 203-204 are supposed to change simultaneously when a glitch is produced in the power line V_{BOOT} so that the voltage difference between the drain terminals of the first pair of NMOS transistors 203-204 remain unchanged and the latch 210 will not be falsely triggered. However, if the first pair of NMOS transistors 203-204 and the second pair of NMOS transistors 205-206 are forced to operate in triode regions due to glitches coupled on the first clock signal CLK and the second clock signal CLKB, the voltage potentials V_{SET} and V_{RESET} at the drain terminals of the first pair of NMOS transistors 203-204 may fall below a threshold voltage and the latch 210 may be falsely triggered.

To solve the problem mentioned above, another level shifter is proposed. Please refer to FIG. 3, which shows a circuit diagram of a prior art level shifter 300 and a latch 310 driven by the level shifter 300, the prior art level shifter 300 being capable of reducing an inherent glitch from a power line of a half-bridge or full-bridge driver. As shown in FIG. 3, the prior art level shifter 300 includes a pair of loading resistors 301-302, a differential pair of transistors 303-304, and a current source transistor 305.

In the prior art level shifter 300, the pair of loading resistors 301-302 have a common end, a pair of output ends, with the common end coupled to a power line V_{BOOT}, the pair of output ends coupled to the transistor 303, and the transistor 304. The differential pair of transistors 303-304 have a pair of gate terminals, a pair of drain terminals, and a common source terminal, with the pair of drain terminals coupled to the output ends, the pair of gate terminals coupled to a first clock signal CLK and a second clock signal CLKB, and the common source terminal coupled to the current source transistor 305. The current source transistor 305 has a drain terminal, a gate terminal and a source terminal, with the drain terminal coupled to the common source terminal of the differential pair of transistors 303-304, the gate terminal coupled to a DC bias voltage V_{B}, and the source terminal coupled to a reference ground, wherein the current source transistor 305 is used to provide a bias current I, and the pair of drain terminals of transistors 303-304 are used to generate a set signal V_{SET} and a reset signal V_{RESET} in response to the first clock signal CLK and the second clock signal CLKB.

The operation principle of the circuit in FIG. 3 can be illustrated by taking the first clock signal CLK being at a high level and the second clock signal CLKB being at a low level as an example. The resulted waveform of the related signals of CLK, CLKB, V_{BOOT}, V_{SET} and V_{RESET} is shown in FIG. 4. When the first clock signal CLK changes from a low level to a high level and the second clock signal CLKB stays at a low level, the transistor 303 will be turned-on and the transistor 304 will be turned-off that the set signal V_{SET} will exhibit a normal negative pulse and the reset signal V_{RESET} will stay at a high level. As can be seen in FIG. 4, the valley of the normal negative pulse of the set signal V_{SET} is below a threshold voltage Vₜₕ, which will cause an effective triggering of the latch 310, and the latch 310 will deliver a high level to drive a high side power switch (not shown in FIG. 3). After a propagation delay t_{PD}, the voltage of the power line V_{BOOT} will rise from V_{DD} to HV+V_{DD}, which will cause a glitch on the first clock signal CLK via a gate-drain parasitic capacitor across the drain terminal and the gate terminal of the transistor 303, and a glitch on the second clock signal CLKB via a gate-drain parasitic capacitor across the drain terminal and the gate terminal of the transistor 304. The glitch on the first clock signal CLK may turn on the transistor 303 and the glitch on the second clock signal CLKB may turn on the transistor 304, so that both the set signal V_{SET} and the reset signal V_{RESET} exhibit an infected negative pulse.

Due to the differential type design, the bias current I in the current source transistor 305 is approximately divided into two currents I/2, I/2 for the transistor 303 and the transistor 304 respectively, so the infected negative pulses of the set signal V_{SET} and the reset signal V_{RESET} will have a valley level V_{L1}, which is much higher than the threshold voltage Vₜₕ to prevent false triggering of the latch 310. However, in a scenario where only the first clock signal CLK or the second clock signal CLKB is coupled with noise, a false triggering of the latch 310 may take place, and the function of the circuit in FIG. 3 will be substantially degraded.

Therefore, there is a demand to provide a robust level shifter for a bridge driver.

### SUMMARY OF THE INVENTION

One objective of the present invention is to provide an effective and robust pulse filter at a low side to prevent a false triggering of a latch of a bridge driver.

Another objective of the present invention is to provide a pulse filter at a low side to reduce the circuit complexity of a bridge driver.

To achieve the foregoing objectives, the present invention provides a bridge driver, including:

a pulse generator, used for generating a first clock signal and a second clock signal, wherein the first clock signal is interleaved with the second clock signal;

a level shifter capable of pulse filtering, used for up shifting the first clock signal and the second clock signal to provide a set signal and a reset signal, and for preventing noise on the first clock signal or on the second clock signal from altering the states of the set signal and the reset signal; and

a latch, used for sending a signal to a driver to switch a high-side power MOSFET according to the set signal and the reset signal.

To make it easier for our examiner to understand the objective of the invention, its structure, innovative features, and performance, we use a preferred embodiment together with the attached drawings for the detailed description of the invention.

### BRIEF DESCRIPTION OF THE DRAWINGS

FIG. 1 shows the architecture of a typical half-bridge driver.

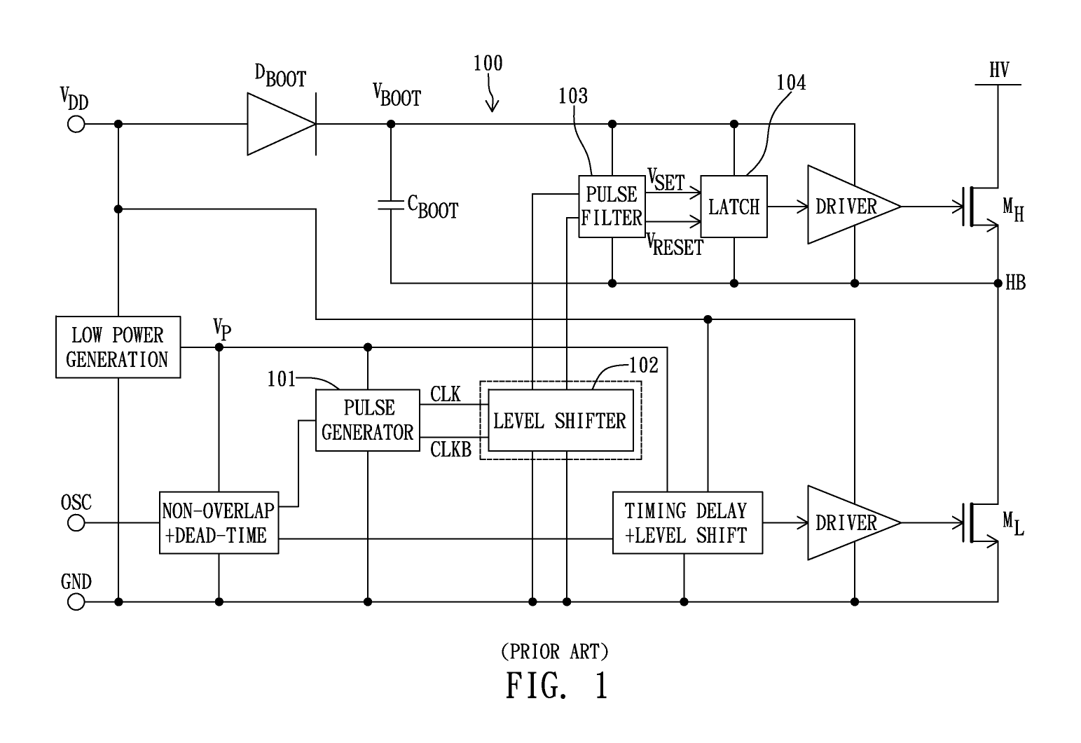

FIG. 2 is a circuit diagram of a prior art level shifter.

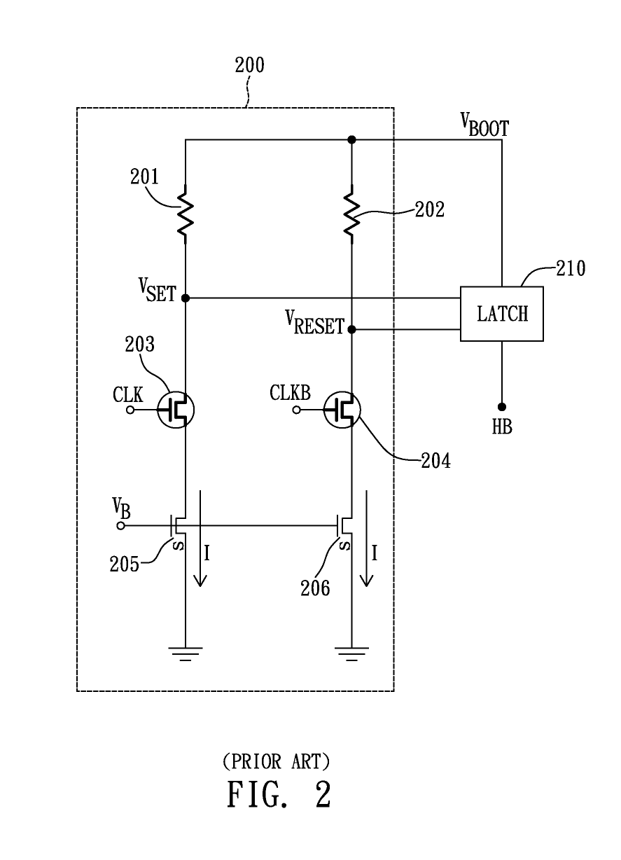

FIG. 3 is a circuit diagram of another prior art level shifter.

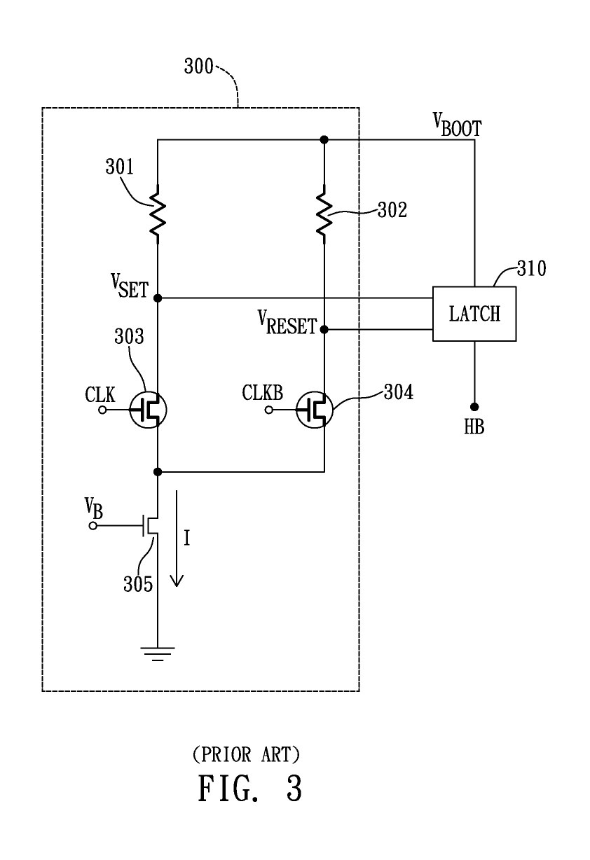

FIG. 4 is a waveform diagram of the circuit in FIG. 3.

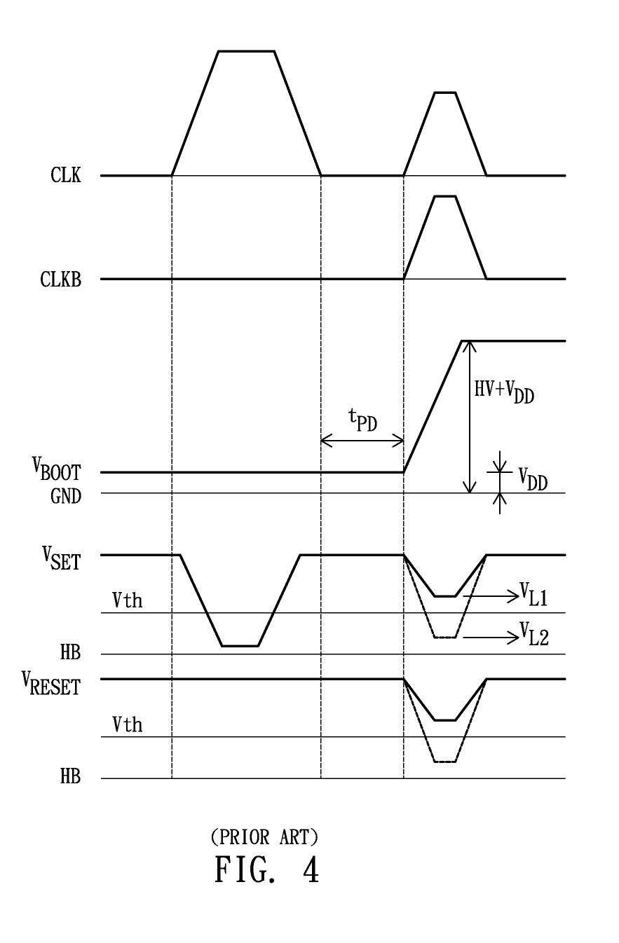

FIG. 5 illustrates a block diagram of a half-bridge driver using a level shifter capable of pulse filtering of the present invention.

FIG. 6 illustrates a circuit diagram of the level shifter capable of pulse filtering of the half-bridge driver in FIG. 5 according to a preferred embodiment of the present invention.

FIG. 7 illustrates a circuit diagram of the level shifter capable of pulse filtering of the half-bridge driver in FIG. 5 according to another preferred embodiment of the present invention.

### DETAILED DESCRIPTION OF THE PREFERRED EMBODIMENTS

The present invention will be described in more detail hereinafter with reference to the accompanying drawings that show the preferred embodiments of the invention.

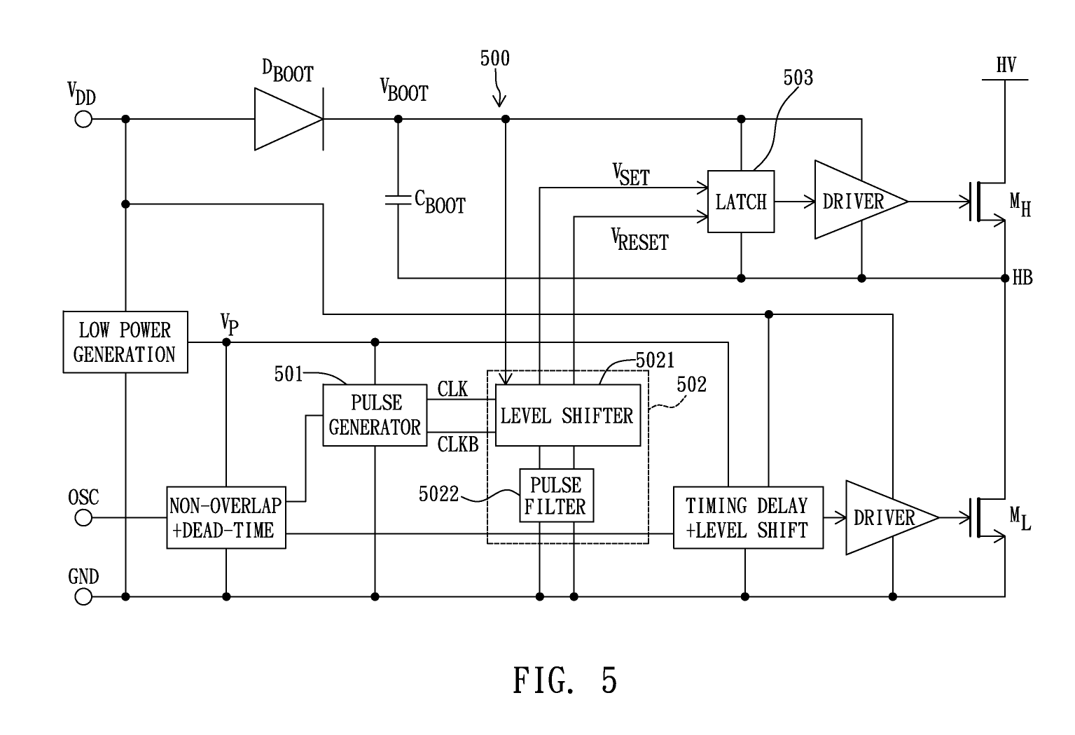

Please refer to FIG. 5, which illustrates a block diagram of a half-bridge driver 500 using a level shifter capable of pulse filtering of the present invention. As illustrated in FIG. 5, the half-bridge driver 500 at least includes a pulse generator 501, a level shifter capable of pulse filtering 502, and a latch 503.

The pulse generator 501 is used for generating a first clock signal CLK and a second clock signal CLKB, wherein the first clock signal CLK is interleaved with the second clock signal CLKB.

The level shifter capable of pulse filtering 502 is used to up shift the first clock signal CLK and the second clock signal CLKB from a low side to provide counterpart signals—a set signal V_{SET} and a reset signal V_{RESET} —for the latch 503 at a high side. The level shifter capable of pulse filtering 502 has a level shifter 5021 and a pulse filter 5022. The pulse filter 5022 is used for preventing noise on the first clock signal CLK or on the second clock signal CLKB from altering the states of the set signal V_{SET} and the reset signal V_{RESET}.

The latch 503 is used for sending a signal to a driver to switch a high-side power MOSFET.

Although a half-bridge driver is used for illustrating the present invention above, it is to be known that the present invention can also be applied in a full-bridge driver.

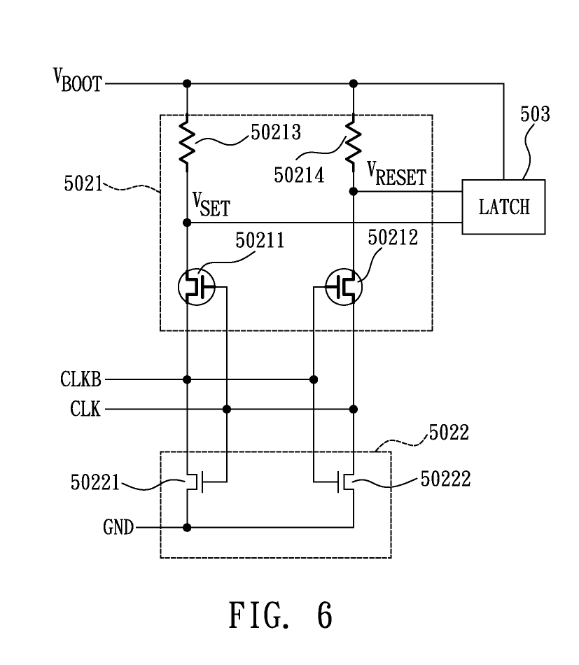

Please refer to FIG. 6, which illustrates a circuit diagram of the level shifter capable of pulse filtering 502 according to a preferred embodiment of the present invention. As illustrated in FIG. 6, the level shifter 5021 has a first NMOS transistor 50211, a second NMOS transistor 50212, a first resistor 50213, and a second resistor 50214; and the pulse filter 5022 has a third NMOS transistor 50221 and a fourth NMOS transistor 50222.

The first NMOS transistor 50211 has a first gate, a first drain, and a first source. The first gate is coupled to the first clock signal CLK. The first drain is used to output the set signal V_{SET}. The first source is coupled to the second clock signal CLKB.

The second NMOS transistor 50212 has a second gate, a second drain, and a second source. The second gate is coupled to the second clock signal CLKB. The second drain is used to output the reset signal V_{RESET}. The second source is coupled to the first clock signal CLK.

The first resistor 50213 has one end coupled to a power line V_{BOOT}, and another end coupled to the first drain of the first NMOS transistor 50211.

The second resistor 50214 has one end coupled to the power line V_{BOOT}, and another end coupled to the second drain of the second NMOS transistor 50212.

The third NMOS transistor 50221 has a third gate, a third drain, and a third source. The third gate is coupled to the first clock signal CLK. The third drain is coupled to the first source of the first NMOS transistor 50211. The third source is coupled to a ground GND.

The fourth NMOS transistor 50222 has a fourth gate, a fourth drain, and a fourth source. The fourth gate is coupled to the second clock signal CLKB. The fourth drain is coupled to the second source of the second NMOS transistor 50212. The fourth source is coupled to the ground GND.

When the first clock signal CLK is at a high level, and the second clock signal CLKB is at a low level, the first NMOS transistor 50211 and the third NMOS transistor 50221 will be turned on, the second NMOS transistor 50212 and the fourth NMOS transistor 50222 will be turned off, and the set signal V_{SET} will be at a low level, and the reset signal V_{RESET} will be at a high level. If the second clock signal CLKB is coupled with a glitch that makes its level rise to a high level, the reset signal V_{RESET} will remain at a high level due to a fact that the second NMOS transistor 50212 is still off—because the second source of the second NMOS transistor 50212 is biased by a high level of the first clock signal CLK.

When the first clock signal CLK is at a low level, and the second clock signal CLKB is at a high level, the first NMOS transistor 50211 and the third NMOS transistor 50221 will be turned off, the second NMOS transistor 50212 and the fourth NMOS transistor 50222 will be turned on, and the set signal V_{SET} will be at a high level, and the reset signal V_{RESET} will be at a low level. If the first clock signal CLK is coupled with a glitch that makes its level rise to a high level, the set signal V_{SET} will remain at a high level due to a fact that the first NMOS transistor 50211 is still off—because the first source of the first NMOS transistor 50211 is biased by a high level of the second clock signal CLKB. As a result, the false triggering of the latch 503 can be avoided.

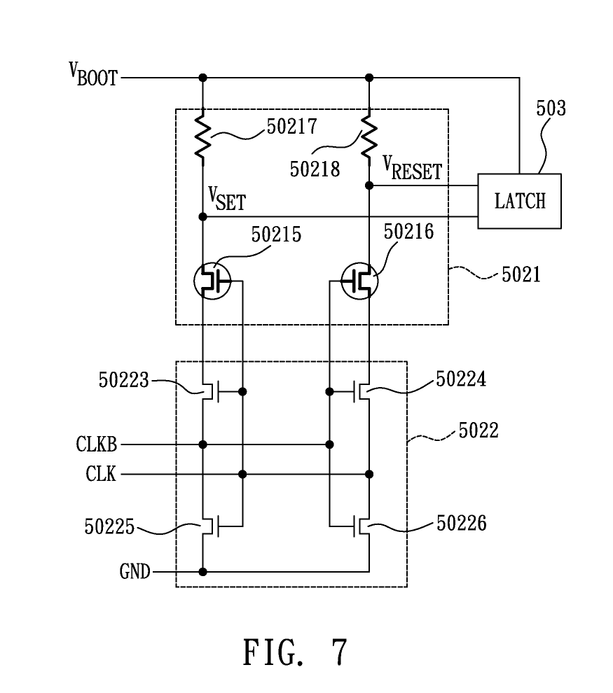

Please refer to FIG. 7, which illustrates a circuit diagram of the level shifter capable of pulse filtering 502 according to another preferred embodiment of the present invention. As illustrated in FIG. 7, the level shifter 5021 has a first NMOS transistor 50215, a second NMOS transistor 50216, a first resistor 50217, and a second resistor 50218; and the pulse filter 5022 has a third NMOS transistor 50223, a fourth NMOS transistor 50224, a fifth NMOS transistor 50225, and a sixth NMOS transistor 50226.

The first NMOS transistor 50215 has a first gate, a first drain, and a first source. The first gate is coupled to the first clock signal CLK. The first drain is used to output the set signal V_{SET}.

The second NMOS transistor 50216 has a second gate, a second drain, and a second source. The second gate is coupled to the second clock signal CLKB. The second drain is used to output the reset signal V_{RESET}.

The first resistor 50217 has one end coupled to a power line V_{BOOT}, and another end coupled to the first drain of the first NMOS transistor 50215.

The second resistor 50218 has one end coupled to the power line V_{BOOT}, and another end coupled to the second drain of the second NMOS transistor 50216.

The third NMOS transistor 50223 has a third gate, a third drain, and a third source. The third gate is coupled to the first clock signal CLK. The third drain is coupled to the first source of the first NMOS transistor 50215. The third source is coupled to the second clock signal CLKB.

The fourth NMOS transistor 50224 has a fourth gate, a fourth drain, and a fourth source. The fourth gate is coupled to the second clock signal CLKB. The fourth drain is coupled to the second source of the second NMOS transistor 50216. The fourth source is coupled to the first clock signal CLK.

The fifth NMOS transistor 50225 has a fifth gate, a fifth drain, and a fifth source. The fifth gate is coupled to the first clock signal CLK. The fifth drain is coupled to the third source of the third NMOS transistor 50223. The fifth source is coupled to a ground GND.

The sixth NMOS transistor 50222 has a sixth gate, a sixth drain, and a sixth source. The sixth gate is coupled to the second clock signal CLKB. The sixth drain is coupled to the second source of the second NMOS transistor 50224. The sixth source is coupled to the ground GND.

When the first clock signal CLK is at a high level, and the second clock signal CLKB is at a low level, the first NMOS transistor 50215, the third NMOS transistor 50223, and the fifth NMOS transistor 50225 will be turned on, the second NMOS transistor 50216, the fourth NMOS transistor 50224, and the sixth NMOS transistor 50226 will be turned off, and the set signal V_{SET} will be at a low level, and the reset signal V_{RESET} will be at a high level. If the second clock signal CLKB is coupled with a glitch that makes its level rise to a high level, the reset signal V_{RESET} will remain at a high level due to a fact that the fourth NMOS transistor 50224 is still off—because the fourth source of the fourth NMOS transistor 50224 is biased by a high level of the first clock signal CLK.

When the first clock signal CLK is at a low level, and the second clock signal CLKB is at a high level, the first NMOS transistor 50211 and the third NMOS transistor 50221 will be turned off, the second NMOS transistor 50212 and the fourth

NMOS transistor 50222 will be turned on, and the set signal V_{SET} will be at a high level, and the reset signal V_{RESET} will be at a low level. If the first clock signal CLK is coupled with a glitch that makes its level rise to a high level, the set signal V_{SET} will remain at a high level due to a fact that the first NMOS transistor 50211 is still off—because the first source of the first NMOS transistor 50211 is biased by a high level of the second clock signal CLKB. As a result, a false triggering of the latch 503 can be avoided.

In conclusion, by placing a pulse filter at the low side, the present invention can use low voltage transistors to cut manufacturing cost, and make the bridge driver more robust.

While the invention has been described by way of examples and in terms of preferred embodiments, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures. For example, another pulse filter may be placed between the level shifter and the latch of the present invention.

In summation of the above description, the present invention herein enhances the performance than the conventional structure and further complies with the patent application requirements and is submitted to the Patent and Trademark Office for review and granting of the commensurate patent rights.

What is claimed is:

1. A level shifter capable of pulse filtering, used in a half-bridge or full-bridge driver, said level shifter capable of pulse filtering comprising:
a first NMOS transistor, having a first gate, a first drain, and a first source, said first gate being coupled to a first clock signal, said first drain being used to output a set signal, and said first source being coupled to a second clock signal, wherein said first clock signal is interleaved with said second clock signal;
a second NMOS transistor, having a second gate, a second drain, and a second source, said second gate being coupled to said second clock signal, said second drain being used to output a reset signal, and said second source being coupled to said first clock signal;
a first resistor, having one end coupled to a power line, and another end coupled to said first drain of said first NMOS transistor;
a second resistor, having one end coupled to said power line, and another end coupled to said second drain of said second NMOS transistor;
a third NMOS transistor, having a third gate, a third drain, and a third source, said third gate being coupled to said first clock signal, said third drain being coupled to said first source of said first NMOS transistor, and said third source being coupled to a ground; and
a fourth NMOS transistor, having a fourth gate, a fourth drain, and a fourth source, said fourth gate being coupled to said second clock signal, said fourth drain being coupled to said second source of said second NMOS transistor, and said fourth source being coupled to said ground.

2. A level shifter capable of pulse filtering, used in a half-bridge or full-bridge driver, said level shifter capable of pulse filtering comprising:
a first NMOS transistor, having a first gate, a first drain, and a first source, said first gate being coupled to a first clock signal, and said first drain being used to output a set signal;
a second NMOS transistor, having a second gate, a second drain, and a second source, said second gate being coupled to a second clock signal, said second drain being used to output a reset signal, wherein said first clock signal is interleaved with said second clock signal;
a first resistor, having one end coupled to a power line, and another end coupled to said first drain of said first NMOS transistor;
a second resistor, having one end coupled to said power line, and another end coupled to said second drain of said second NMOS transistor;
a third NMOS transistor, having a third gate, a third drain, and a third source, said third gate being coupled to said first clock signal, said third drain being coupled to said first source of said first NMOS transistor, and said third source being coupled to said second clock signal;
a fourth NMOS transistor, having a fourth gate, a fourth drain, and a fourth source, said fourth gate being coupled to said second clock signal, said fourth drain being coupled to said second source of said second NMOS transistor, and said fourth source being coupled to said first clock signal;
a fifth NMOS transistor, having a fifth gate, a fifth drain, and a fifth source, said fifth gate being coupled to said first clock signal, said fifth drain being coupled to said third source of said third NMOS transistor, and said fifth source being coupled to a ground; and
a sixth NMOS transistor, having a sixth gate, a sixth drain, and a sixth source, said sixth gate being coupled to said second clock signal, said sixth drain being coupled to said second source of said second NMOS transistor, and said sixth source being coupled to said ground.

3. A bridge driver, comprising:
a pulse generator, used for generating a first clock signal and a second clock signal, wherein said first clock signal is interleaved with said second clock signal;
a level shifter capable of pulse filtering, used for up shifting said first clock signal and said second clock signal to provide a set signal and a reset signal, and for preventing noise on said first clock signal or on said second clock signal from altering the states of said set signal and said reset signal; and
a latch, used for sending a signal to a driver to switch a high-side power MOSFET according to said set signal and said reset signal.

4. The bridge driver as claim 3, wherein said bridge driver is a half-bridge driver or a full-bridge driver.

5. The bridge driver as claim 3, wherein said level shifter capable of pulse filtering comprising:
a first NMOS transistor, having a first gate, a first drain, and a first source, said first gate being coupled to said first clock signal, said first drain being used to output said set signal, and said first source being coupled to said second clock signal;
a second NMOS transistor, having a second gate, a second drain, and a second source, said second gate being coupled to said second clock signal, said second drain being used to output said reset signal, and said second source being coupled to said first clock signal;
a first resistor, having one end coupled to a power line, and another end coupled to said first drain of said first NMOS transistor;
a second resistor, having one end coupled to said power line, and another end coupled to said second drain of said second NMOS transistor;
a third NMOS transistor, having a third gate, a third drain, and a third source, said third gate being coupled to said first clock signal, said third drain being coupled to said first source of said first NMOS transistor, and said third source being coupled to a ground; and
a fourth NMOS transistor, having a fourth gate, a fourth drain, and a fourth source, said fourth gate being coupled to said second clock signal, said fourth drain being coupled to said second source of said second NMOS transistor, and said fourth source being coupled to said ground.

6. The bridge driver as claim 3, wherein said level shifter capable of pulse filtering comprising:
a first NMOS transistor, having a first gate, a first drain, and a first source, said first gate being coupled to said first clock signal, and said first drain being used to output said set signal;
a second NMOS transistor, having a second gate, a second drain, and a second source, said second gate being coupled to said second clock signal, said second drain being used to output said reset signal;
a first resistor, having one end coupled to a power line, and another end coupled to said first drain of said first NMOS transistor;
a second resistor, having one end coupled to said power line, and another end coupled to said second drain of said second NMOS transistor;
a third NMOS transistor, having a third gate, a third drain, and a third source, said third gate being coupled to said first clock signal, said third drain being coupled to said first source of said first NMOS transistor, and said third source being coupled to said second clock signal;
a fourth NMOS transistor, having a fourth gate, a fourth drain, and a fourth source, said fourth gate being coupled to said second clock signal, said fourth drain being coupled to said second source of said second NMOS transistor, and said fourth source being coupled to said first clock signal;
a fifth NMOS transistor, having a fifth gate, a fifth drain, and a fifth source, said fifth gate being coupled to said first clock signal, said fifth drain being coupled to said third source of said third NMOS transistor, and said fifth source being coupled to a ground; and
a sixth NMOS transistor, having a sixth gate, a sixth drain, and a sixth source, said sixth gate being coupled to said second clock signal, said sixth drain being coupled to said second source of said second NMOS transistor, and said sixth source being coupled to said ground.
